(19) United States
(12) Patent Application Publication
(10) Pub. No.: US 2026/0227460 A1
(43) Pub. Date: Aug. 6, 2026

(54) CURRENT MEASUREMENT

(71) Applicant: STMicroelectronics International N.V., Geneva (CH)

(72) Inventor: Christale CROUARD, TOULOUSE (FR)

(73) Assignee: STMicroelectronics International N.V., Geneva (CH)

(21) Appl. No.: 19/464,417

(22) Filed: Jan. 29, 2026

(30) Foreign Application Priority Data
Feb. 5, 2025 (FR) FR2501165

(51) Int. Cl. G01R 31/52; G01R 31/26; G01R 31/327

(52) U.S. Cl. CPC G01R 31/52; G01R 31/2621; G01R 31/3277

(57) ABSTRACT

A circuit measures a leakage current of a first switch during a non-conductive state of the first switch. The circuit includes a current measurement assembly and a second switch parallelly mounted. The second switch is suitable for receiving a first control signal synchronized with a second control signal of the first switch.

### CROSS-REFERENCE TO RELATED APPLICATION

This application claims the priority benefit of French patent application number FR2501165, filed on February 5, 2025, entitled “Mesure d’un courant,” which is hereby incorporated by reference to the maximum extent allowable by law.

### BACKGROUND

### Technical Field

The present disclosure generally relates to electronic systems and devices and more particularly to electronic systems and devices including solutions for measuring a current. More specifically, the present disclosure relates to a circuit for measuring the leakage current in a switch, such as a transistor.

### Description of the Related Art

Most electronic components, such as switches or transistors, may have leakage current causing power losses. To minimize these losses, and, for example, evaluate the state of health of a switch, it could be of importance to know accurately measuring these leakage currents.

It would be desirable to be able to improve at least in part some aspects of current measurement circuits, and particularly some aspects of circuits for measuring leakage current in switches.

### BRIEF SUMMARY

There is a need for more accurate current measurement circuits.

There is a need for more accurate circuits for measuring leakage current in electronic components.

There is a need for more accurate circuits for measuring leakage current in switches, such as transistors.

There is a need for circuits for measuring leakage current of switches during their switching operations during non-conducting state phases.

There is a need for switch leakage current measurement circuits and detection circuits protected from surges and transient currents during switching.

One embodiment overcomes some or part of the drawbacks of known current measurement circuits.

One embodiment provides a more accurate current measurement circuit.

One embodiment provides a more accurate circuit for measuring leakage current in a switch.

One embodiment provides a circuit for measuring a leakage current of a first switch during a non-conductive state of the first switch, including a current measurement assembly and a second switch parallelly mounted, the second switch being suitable for receiving a first control signal synchronized on a second control signal of the first switch.

Another embodiment provides a method for measuring a leakage current of a first switch during a non-conductive state of the first switch, including a step for using a circuit for measuring a leakage current including a current measurement assembly and a second switch parallelly mounted, the second switch being suitable for receiving a first control signal synchronized on a second control signal of the first switch.

According to an embodiment, the current measurement assembly is suitable for measuring a current flowing through the first switch as it is conductive.

According to an embodiment, the second switch is suitable for receiving a minimum intensity current equal to the intensity of a current flowing through the first switch as it is conductive.

Another embodiment provides an electronic device including a circuit previously-described, and the first switch.

According to an embodiment, the circuit is coupled between a first conduction terminal of the first switch and a load.

According to an embodiment, the circuit is coupled between a second conduction, different from the first conduction terminal, of the first switch and a terminal suitable for receiving a reference potential.

According to an embodiment, the first switch is a power transistor.

According to an embodiment, the first switch is a high mobility electronic transistor.

According to an embodiment, the circuit further includes a control unit suitable for providing the first and second control signals.

According to an embodiment, the control unit includes:

at least one logic circuit;

a first driver circuit of the first switch; and

a second driver circuit of the second switch.

According to an embodiment, the control unit further includes:

at least one RC filter; and

at least one Schmitt trigger.

According to an embodiment, an electronic device includes a first switch, a circuit coupled to the first switch and including a current measurement assembly and a second switch coupled in parallel with the current measurement assembly and configured to receive a first control signal synchronized on a second control signal of the first switch.

According to an embodiment, a method includes providing a first control signal to a first switch, providing, to a second switch of a circuit, a second control signal synchronized with the first control signal, and measuring, with a current measurement assembly of the circuit connected in parallel with the second switch, a leakage current of the first switch while the first switch is in a non-conductive state.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 illustrates an embodiment of an electronic device including a transistor and a measurement circuit according to one embodiment;

FIG. 2 illustrates graphics illustrating an operating mode of the embodiment shown in FIG. 1;

FIG. 3 illustrates under block form an embodiment of a control circuit of the embodiment shown in FIG. 1;

FIG. 4 illustrates a practical example embodiment of the embodiment shown in FIG. 1;

FIG. 5 illustrates a practical example embodiment of the circuit shown in FIG. 3;

FIG. 6 illustrates graphics illustrating the operation of the examples shown in FIGS. 4 and 5;

FIG. 7 illustrates other graphics illustrating the operation of the examples shown in FIGS. 4 and 5; and

FIG. 8 illustrates another embodiment of an electronic device including a transistor and a measurement circuit according to one embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

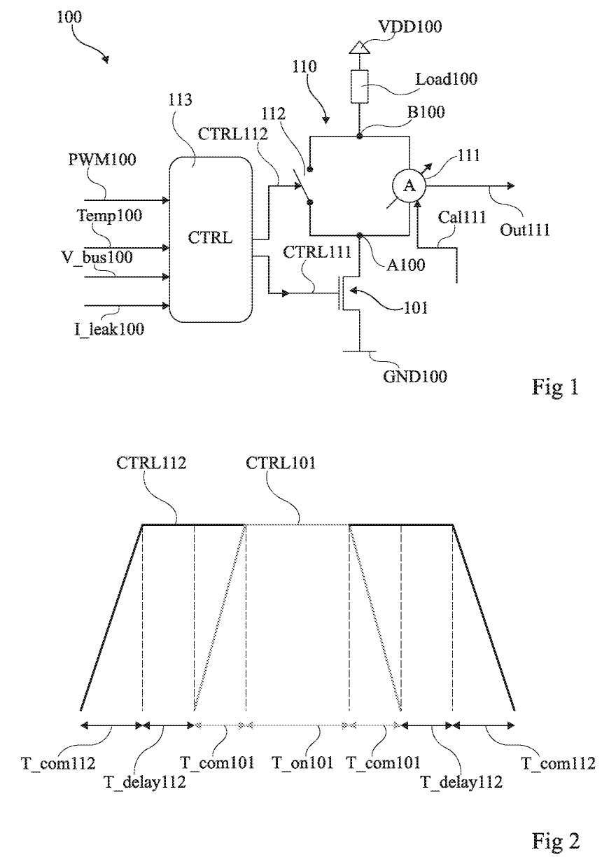

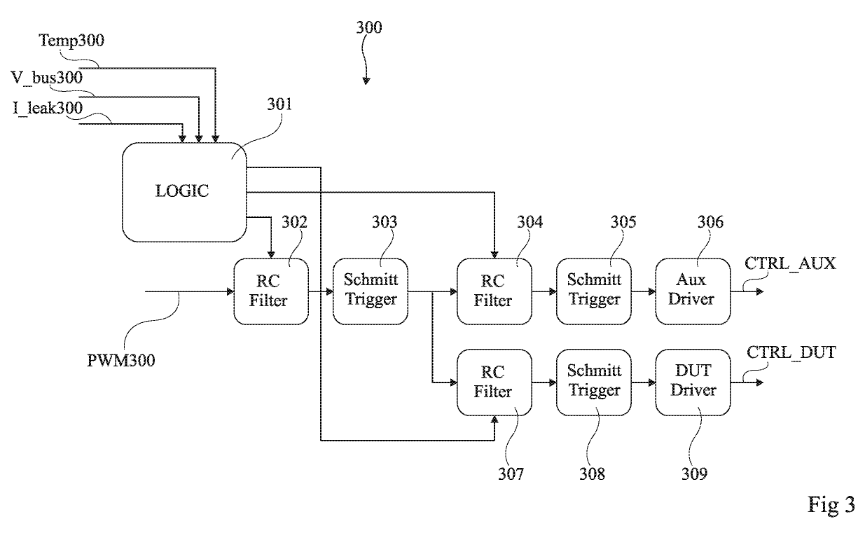

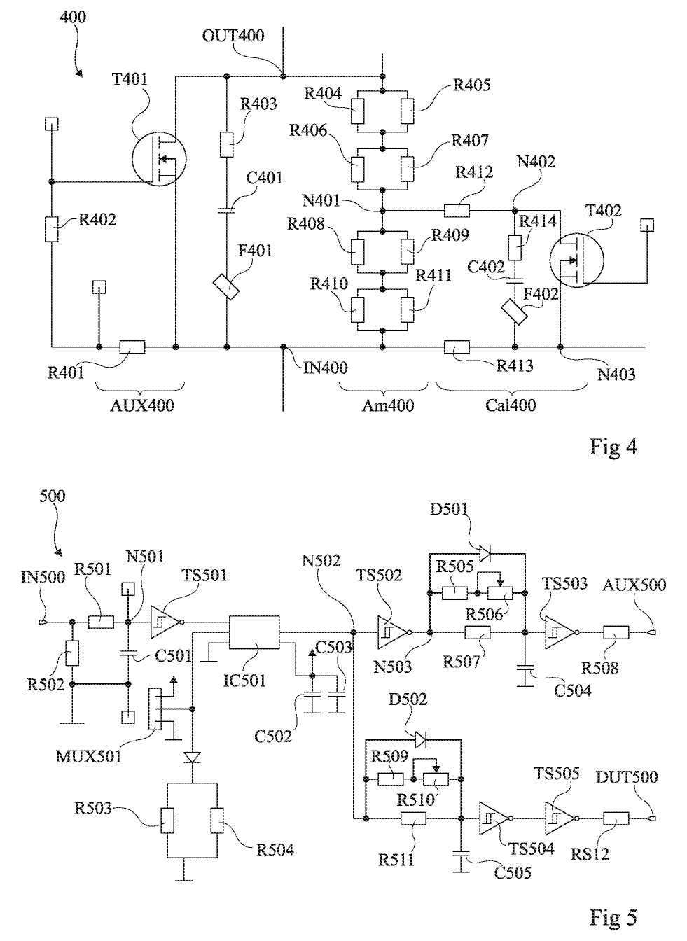

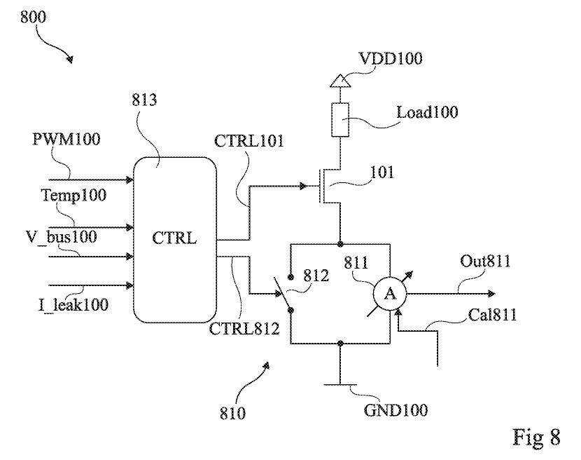

The hereinafter described embodiments relate to current measurements and more particularly to measurements of leakage current in electronic components such as switches as transistors. These embodiments provide a control circuit adapted to measure a leakage current in a switch during a non-conductive phase. This measurement circuit includes a current measurement assembly arranged in parallel with another switch, for example a transistor the signal for controlling the which is synchronized with the control signal of the switch the leakage current of which is to be measured. FIGS. 1 and 8 show two ways for connecting such a measurement circuit to a switch. FIG. 2 illustrates the operation of such a measurement circuit. FIG. 3 illustrates an example embodiment of a control circuit of such a measurement circuit. FIGS. 4-7 show a practical case of an embodiment.

In addition, the hereinafter described embodiments are especially suitable for products formed on structures including gallium nitride (GaN) having integrated logic circuits for example to implement integrated intelligence operations. These embodiments can further be suitable for devices in the fields of power supplying and of voltage converting.

In addition, the hereinafter described embodiments are especially suitable for use in any type of industrial markets where measuring current is called for. More particularly, such a current measurement circuit could be intended to:

the automotive industry, for example in the field of car electrification or the field of advanced driver assistance systems (ADAS);

the industrial market, for example in the field of green energy, in the field of electrification of infrastructure, of the internet of things (IoT), and of smart homes, wherein power and energy consumption and data exchange are key elements;

the personal electronics industry, for example in the field of mobile phone and of the internet of things (IoT), as well as in the field of high speed-interface; and

the communications equipment, computers and peripherals industry, for example in the field of infrastructure and data centers, and in the field of satellites in low earth orbit (LEO).

FIG. 1 schematically illustrates an embodiment of an electronic device 100 including a switch 101, and an embodiment of a current measurement circuit 110 suitable for measuring a leakage current in the switch 101.

According to one example, the switch 101 is a transistor. According to a first example, the switch 101 can be a bipolar transistor, for example a NPN-type transistor or a PNP-type transistor. According to a second example, the switch 101 can be a metal-oxide-semiconductor field-effect transistor, or MOSFET transistor, or MOS transistor. More particularly, transistor 101 can be a N-channel MOS transistor, or N-type MOS transistor, or NMOS transistor, or can be a P-channel MOS transistor, or P-type MOS transistor, or PMOS transistor. According to a third example, the switch 101 can be an Insulated Gate Bipolar Transistor (IGBT) 101. According to a fourth example, the switch 101 can be a transistor formed in and on a structure including gallium nitride (GaN), or silicon carbide (SiC), and be a High Electron Mobility Transistor (HEMT), also referred to as modulated-doping field effect transistor, (MODFET). More particularly, the switch 101 can be a depletion-mode HEMT transistor, or d-mode HEMT transistor, or d-mode transistor, or can be an enhancement mode HEMT transistor, or e-mode-type HEMT transistor, or e-mode transistor. Other example types of transistors the switch 101 could be obvious to those skilled in the art. According to one example, transistor 101 can be a power transistor.

According to another example, the switch 101 is a relay, and the current measuring circuit 110 is adapted to measure the leakage current of the main branch of the relay.

According to one example, a first conduction terminal of the first switch 101 is coupled, preferably connected, to a terminal suitable for receiving a reference potential GND100, for example ground. According to one example, a second conduction terminal of the first switch 101 is coupled, preferably connected, to an input terminal A100 of the current measurement circuit 110. According to one example, a control terminal of the switch 101 is suitable for receiving a control signal CTRL101.

According to one example, the device 100 further includes a load. Load 100 including a first terminal coupled, preferably connected, to an output terminal B100 of the current measurement circuit 110, and including a second terminal coupled, preferably connected, to a terminal suitable for receiving a supply potential VDD100. According to one example, the supply potential VDD100 differs from the reference potential GND100, and is higher than the reference potential GND100, for example.

According to one embodiment, the current measurement circuit 110 includes a current measurement assembly 111 and a switch 112. The assembly 111 and the switch 112 are parallelly mounted between terminals A100 and B100.

According to one embodiment, the assembly 111 could be a current measurement solution 111 of any type, for example an amperemeter. An input terminal of the assembly 111 is coupled, preferably connected, to the input terminal A100 of the circuit 110, and an output terminal of the assembly 111 is coupled, preferably connected, to the output terminal B100 of the circuit 110. For example, the assembly 111 is suitable for providing an output signal Out111 representative of the value of current that it measures. For example, the assembly 111 is suitable for receiving a calibration signal Cal111.

According to one embodiment, the assembly 111 is sized to measure the value of the current flowing through the switch 101 when it is turned conductive.

According to one embodiment, the switch 112 is a transistor. According to a first example, the switch 112 can be a bipolar transistor, for example a NPN-type transistor or a PNP-type transistor. According to a second example, the switch 112 can be a MOS transistor, such as a NMOS or PMOS transistor. According to a third example, the switch 112 can be an insulated gate bipolar transistor 112. According to a fourth example, the switch 112 can be a transistor formed in and on a structure including gallium nitride (GaN), and be an HEMT-type transistor, for example of the d-mode type or the e-mode type. Other examples of transistor type that the switch 112 can have are obvious to those skilled in the art.

According to one embodiment, a first conduction terminal of the switch 112 is coupled, preferably connected, to the input terminal A100 of the circuit 110. According to one example, a second conduction terminal of the switch 112 is coupled, preferably connected, to the input terminal B100 of the current measurement circuit 110. According to one example, a control terminal of the switch 112 is suitable for receiving a control signal CTRL112.

According to one embodiment, the switch 112 is a transistor sized to be able to withstand the same current level as switch 101. In other words, the switch 112 as it is turned conductive, is able to be passed through by a current at least equal to the maximum current flowing through the switch 101 as it is turned conductive.

According to one embodiment, the switch 112 is a transistor sized to have a minimum leakage current. More precisely, the leakage current of the transistor 112 must represent less than 5% of the smallest current value that the measuring circuit is sized to measure. According to a specific example, if it is hoped at best to measure a current of the order of 100 nA flowing through the switch 101, it is beneficial for the transistor 112 to have a leakage current of less than 5 nA to obtain 5% accuracy on the measurement.

According to a preferred embodiment, the switch 112 is a transistor sized to quickly switch. According to one example, the switch 112 has a switching speed higher than the switching speed of the switch 101. According to another embodiment, the switch 112 may be a transistor that switches more slowly than the switch 101, in which case it is preferable to adapt the frequency to the switching frequency of the switch 101.

According to one embodiment, the measurement circuit 110 further includes a control circuit 113 (CTRL) suitable for providing the control signal CTRL112. According to one example, the control circuit 113 is further suitable for providing the control signal CTRL101.

According to a first example, the control circuit 113 is suitable for receiving a signal PWM100 provided for example by a pulse width modulation circuit. According to one example, the control circuit 113 is suitable for possibly receiving:

a signal Temp100 representative of information relative to the temperature of the surroundings where device 100 is;

a signal V_bus100 representative of a data signal processed by device 100; and

signal I_leak100 representative of information relative to the leakage current measured by assembly 111.

A detailed example control circuit 113 is described in relation to FIG. 3.

According to a second example, the control circuit 113 (CTRL) may be a digital control circuit controlled by a user. Such a digital control circuit may use a signal generator, a microcontroller, integrated circuits with a programmable hardware structure (FPGA, Field Programmable Gate Arrays).

The operation of the control circuit 110 is described in relation to FIG. 2.

FIG. 2 illustrates the shapes of portions of the control signals CTRL101 and CTRL112 described in relation to FIG. 1.

According to one embodiment, the measurement circuit 110 is suitable for measuring a leakage current of the switch 101 even during a non-conductive state. To this end, and according to one embodiment, the control signals CTRL101 and CTRL112 of switches 101 and 112 are synchronized. In other words, the control signals CTRL101 and CTRL112 are generated to have high states at the same time, and low states at the same time.

More particularly, the control signal CTRL101 is generated to turn the switch 112 conductive. Once this state is reached, the switch 101 is made conductive, the measuring circuit is thus protected during the conduction phase of the switch 101 since the measurement is not possible. When the switch 101 becomes non-conductive, the transistor 112 also becomes non-conductive, and the measuring circuit is again protected during the descent phase towards non-conduction.

More specifically, a conduction phase of the switch 101 is defined by a duration T_on101, and switching phases, from the conductive state to the non-conductive state, or from the non-conductive state to the conductive state, of the switch 101 are defined by a duration T_com101. The duration of the conduction phase of switch 112 has a minimum duration equal to the sum of the duration T_on101 and two times the duration T_com101. For safety, it is possible to add one or two durations T_delay112 to the duration of the conduction phase of the switch 112. Phases of switching from the conductive state to the non-conductive state, or from the non-conductive state to the conductive state, of the switch 112 are defined by a duration T_com112.

During a conduction phase of switch 112, the switch 101 has thus always a phase of switching from a conductive state to a non-conductive state. During this switching phase, assembly 111 is then able to measure the value of the leakage current in the switch 101. Furthermore, the time called for to make this measurement and the different durations defined previously, make it possible to define the maximum switching frequency of the switch 101 and the transistor 112.

FIG. 3 illustrates an example embodiment of a control circuit 300 of the type of the control circuit 113 described in relation to FIG. 1.

As the control circuit 113, the control circuit 300 is suitable for receiving as input:

a signal PWM300 provided for example by a pulse width modulation circuit;

possibly, a signal Temp300 representative of information relative to the temperature of the surroundings of the device including the circuit 300;

possibly, a signal V_bus300 representative of a data signal processed by the device including the circuit 300; and

possibly, a signal I_leak300 representative of information relative to the leakage current measured by a measurement circuit of the type of the measurement circuit 110 described in relation to FIG. 1.

As control circuit 113, the control circuit 300 is suitable for providing as output:

a control signal CTRL_AUX suitable for controlling a switch of the type of the switch 112 described in relation to FIG. 1; and

a control signal CTRL_DUT suitable for controlling a switch of the type of the switch 101 described in relation to FIG. 1.

According to one example, the control circuit 300 includes one or more logic circuits 301 (LOGIC) suitable for receiving the possible signals Temp300, V_bus300 and I_leak300, and to provide indications to the other circuits of the circuit 300.

According to one example, the control circuit 300 further includes a first RC-type filter circuit (RC Filter). This circuit is suitable for receiving the signal PWM300, and for receiving indications from the one or more logic circuits 301.

According to one example, the control circuit 300 further includes a first trigger of the Schmitt Trigger 303 (Schmitt Trigger) suitable for receiving as input the signal provided as output by circuit 302.

According to one example, the control circuit 300 further includes a second RC-type filter circuit (RC Filter). This circuit is suitable for receiving an output signal of the trigger 303, and for receiving indications from the one or more logic circuits 301.

According to one example, the control circuit 300 further includes a second trigger of the Schmitt Trigger type 305 (Schmitt Trigger) suitable for receiving as input the signal provided as output by circuit 304.

According to one example, the control circuit 300 further includes a first driver circuit 306 (Aux Driver) suitable for delivering the control signal CTRL_AUX from the signal delivered by trigger 305.

According to one example, the control circuit 300 further includes a third RC-type filter circuit 307 (RC Filter). This circuit is suitable for receiving an output signal of the trigger 303, and for receiving indications from the one or more logic circuits 301.

According to one example, the control circuit 300 further includes a third trigger of the Schmitt Trigger type 308 (Schmitt Trigger) suitable for receiving as input the signal provided as output by circuit 307.

According to one example, the control circuit 300 further includes a second driver circuit 309 (DUT Driver) suitable for delivering the control signal CTRL_DUT from the signal delivered by trigger 305.

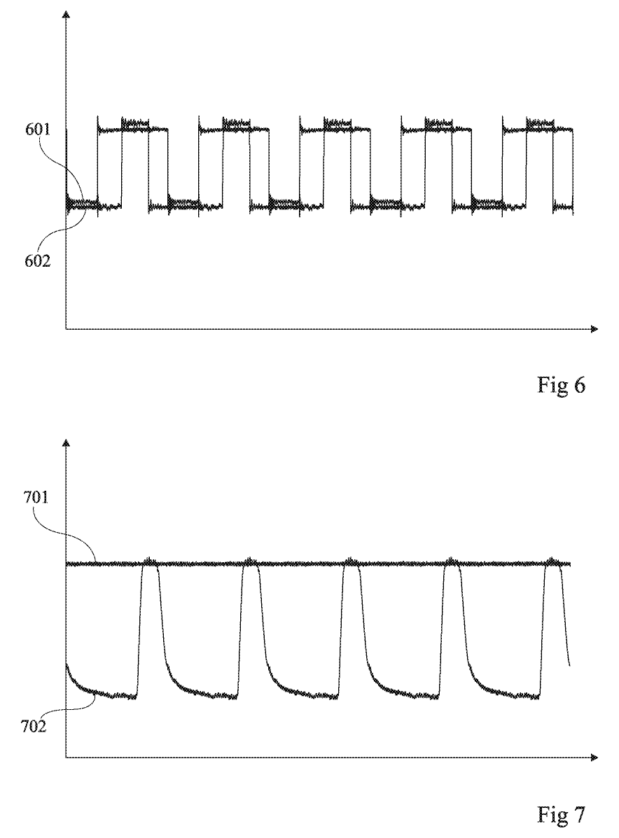

FIGS. 4 and 5 are electronic diagram of a practical example implementation of the current measurement circuit 110 described in relation to FIG. 1. FIG. 4 is an electronic diagram of a part 400 of the current measurement circuit 113 including assembly 111 and switch 112. FIG. 5 is an electronic diagram of a part 500 of the current measurement circuit 113 including the control circuit 113.

According to one example, the part 400 includes a switch AUX400 of the type of the switch 112 described in relation to FIG. 1, a current measurement assembly Am400 of the type of assembly 111 described in relation to FIG. 1, and according to one example, a calibration circuit Ca1400.

According to one embodiment, an input terminal of the part 400 is referenced IN400, and an output terminal of the part 400 is referenced OUT400.

According to one example, the switch AUX400 includes a transistor T401 of the NMOS-type and two resistors R401 and R402. A source terminal of the transistor T401 is coupled, preferably connected, to the input terminal IN400, and a drain terminal of the transistor T401 is coupled, preferably connected, to the output terminal OUT400. The resistors R401 and R402 are serially coupled, preferably connected, to each other, and couple the source terminal of transistor T401 to the gate terminal of transistor T401.

According to one example, part 400 further includes a filter serial assembly coupling the input IN400 and output OUT400 terminals. This assembly includes a resistor R403, a capacitor C401, and a ferrite core F401. According to one example, a first terminal of resistor R403 is coupled, preferably connected, to the output terminal OUT400, and a second terminal of resistor R403 is coupled, preferably connected, to a first terminal of capacitor C401. A second terminal of capacitor C401 is coupled, preferably connected, to a first terminal of the ferrite core F401, and a second terminal of the ferrite core F401 is coupled, preferably connected, to the input terminal IN400.

According to one example, assembly Am400 includes eight resistors R404 to R411. A first terminal of resistor R404 is coupled, preferably connected, to the output terminal OUT400, and to a first terminal of resistor R405. A second terminal of resistor R404 is coupled, preferably connected, to a second terminal of the resistor R405 and to first terminals R406 and R407. Second terminals of resistors R406 and R407 are coupled to each other and to a node N401. A first terminal of resistor R408 is coupled, preferably connected, to node N401 and to a first terminal of resistor R409. A second terminal of resistor R408 is coupled, preferably connected, to a second terminal of resistor R409 and to first terminals of resistors R410 and R411. Second terminals of resistors R410 and R411 are coupled to each other and to the input terminal IN400.

According to one example, the calibration circuit Cal400 is formed between node N101 and input terminal IN400. According to one example, circuit Cal400 includes two resistors R412 and R413, a transistor T402 and a filter serial assembly. According to one example, a first terminal of resistor R412 is coupled, preferably connected, to node N401 and a second terminal of resistor R412 is coupled, preferably connected, to a node N402. According to one example, a first terminal of resistor R413 is coupled, preferably connected, to input terminal IN400, and a second terminal of the resistor R413 is coupled, preferably connected, to a node N403. According to one example, the transistor T402 is of the NMOS type. According to one example, a source terminal of transistor T402 is coupled, preferably connected, to node N403, and a drain terminal of transistor T402 is coupled, preferably connected, to node N402. A gate terminal of transistor T402 is suitable for receiving a calibration signal of the type of signal Cal111 described in relation to FIG. 1. According to one example, the filter serial assembly couples nodes N402 and N403. This assembly includes a resistor R414, a capacitor C402, and a ferrite core F402. According to one example, a first terminal of resistor R414 is coupled, preferably connected, to node N402, and a second terminal of resistor R414 is coupled, preferably connected, to a first terminal of capacitor C402. A second terminal of capacitor C402 is coupled, preferably connected, to a first terminal of ferrite core F402, and a second terminal of ferrite core F402 is coupled, preferably connected, to node N403.

According to one example, part 500 includes an input terminal IN500 and two output terminals AUX500 and DUT500. The output terminal AUX500 is suitable for delivering a control signal to transistor T401 of FIG. 4. Output terminal DUT500 is suitable for delivering an output signal to a switch to be tested, for example switch 101 shown in FIG. 1.

According to one example, part 500 includes two resistors R501 and R502, a capacitor C501, and a trigger TS501 of the Schmitt trigger type. A first terminal of the resistor R501 is coupled, preferably connected, to terminal IN500 and to a first terminal of resistor R502, and a second terminal of resistor R501 is coupled, preferably connected, to a first terminal of capacitor C501 and to an input terminal, referenced N501, of trigger TS501. A second terminal of resistor R502 is coupled, preferably connected, to a second terminal of capacitor C501.

According to one example, part 500 further includes an integrated circuit IC501, a multiplexer MUX501, two resistors R503 and R504, and two capacitors C502 and C503. A first terminal A of circuit IC501 is coupled, preferably connected, to an output terminal of trigger TS501, a second terminal B of the circuit IC501 is coupled, preferably connected, to an output of multiplexer MUX501 and to first terminals of resistors R503 and R504. Second terminals of resistors R503 and R504 are coupled to each other. A terminal GND of circuit IC501 is coupled, preferably connected, to a terminal receiving a reference potential, for example ground. A switching terminal VCC of circuit IC501 is coupled to first terminals of capacitors C502 and C503. An output terminal Y of circuit IC501 is coupled, preferably connected, to a node N502.

According to one example, part 500 further includes two triggers TS502 and TS503 of the Schmitt Trigger type, four resistors R505 to R508, a diode D501, and a capacitor C504. An input terminal of trigger TS502 is coupled, preferably connected, to a node N502, and an output terminal of trigger TS502 is coupled, preferably connected, to a node N503. An anode terminal of diode D501 is coupled, preferably connected, to node N503, and a cathode terminal of diode D501 is coupled, preferably connected, to an input terminal of trigger TS503. A first terminal of resistor R505 is coupled, preferably connected, to node N503, and a second terminal of resistor R505 is coupled, preferably connected, to a first terminal of resistor R506. A second terminal of resistor R506 is coupled, preferably connected, to the input terminal of trigger TS503. A first terminal of resistor R507 is coupled, preferably connected, to node N503, and a second terminal of resistor R507 is coupled, preferably connected, to the input terminal of trigger TS503. A first terminal of capacitor C504 is coupled, preferably connected, to the input terminal of trigger TS503. A first terminal of resistor R508 is coupled, preferably connected, to an output terminal of trigger TS503, and a second terminal of resistor R508 is coupled, preferably connected, to terminal AUX500.

According to one example, part 500 further includes two triggers TS504 and TS505 of the Schmitt Trigger type, four resistors R509 to R512, a diode D502, and a capacitor C505. An anode terminal of diode D502 is coupled, preferably connected, to node N502, and a cathode terminal of diode D502 is coupled, preferably connected, to an input terminal of trigger TS504. A first terminal of resistor R509 is coupled, preferably connected, to node N502, and a second terminal of resistor R509 is coupled, preferably connected, to a first terminal of resistor R510. A second terminal of resistor R510 is coupled, preferably connected, to input terminal of trigger TS504.A first terminal of resistor R511 is coupled, preferably connected, to node N502, and a second terminal of resistor R511 is coupled, preferably connected, to the input terminal of trigger TS504. A first terminal of capacitor C505 is coupled, preferably connected, to the input terminal of trigger TS504. An output terminal of trigger TS504 is coupled, preferably connected, to an input terminal of trigger TS505. A first terminal of resistor R512 is coupled, preferably connected, to an output terminal of trigger TS505, and a second terminal of resistor R512 is coupled, preferably connected, to terminal DUT500.

FIG. 6 is a graphic illustrating the operation of a control circuit of the type of the control circuit 113 described in relation to FIG. 1.

The graphic shown in FIG. 6 includes:

a curve 601 illustrating a signal for controlling the switch of the current measurement circuit; and

a curve 602 illustrating a signal for controlling the switch the leakage current of which is measured.

These curves illustrate in more detail the operation described in relation to FIG. 2.

FIG. 7 is a graphic illustrating the operation of a current measurement circuit of the type of the circuit 110 described in relation to FIG. 1.

The graphic shown in FIG. 7 includes:

a curve 701 illustrating a voltage applied to the transistor the current of which is to be measured; and

a curve 702 illustrating the evolution of the leakage current of the transistor to be measured.

These curves effectively show that the circuit according to one embodiment allows the leakage current during a non-conductive state of the switch to be measured.

FIG. 8 schematically illustrates an embodiment of an electronic device 800 including the switch 101, and an embodiment of a current measurement circuit 810 suitable for measuring a leakage current of the switch 101.

Device 800 is similar to device 100 described in relation to FIG. 1. The features common to devices 100 and 800 are not described in detail. Only differences between devices 100 and 800 are highlighted.

According to one example, device 800 differs from device 100 in that the current measurement circuit 810 is disposed between the terminal of switch 101 receiving the reference potential and the terminal delivering the reference potential, and not between switch 101 and load Load 100.

The measurement circuit 810 is identical to circuit 110 described in relation to FIG. 1. Particularly, the measurement circuit 810 includes:

a current measurement assembly 811 (A) of the type of assembly 111, delivering a signal Out811, and suitable for receiving a calibration signal Call811;

a switch 812 of the type of switch 112; and

a control circuit 813 suitable for receiving signals PWM100, Temp100, V_bus100, and I_leak100, and for delivering a control signal CTRL812 of switch 812, and control signal CTRL101.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

In one embodiment, a circuit for measuring (110; 810) a leakage current of a first switch (101) during a non-conductive state of the first switch (101) includes a current measurement assembly (111; 811) and a second switch (112; 812) parallelly mounted, the second switch (112; 812) being suitable for receiving a first control signal (CTRL112; CTRL812) synchronized on a second control signal (CTRL101) of the first switch (101).

In one embodiment, a method for measuring a leakage current of a first switch (101) during a non-conductive state of the first switch (101), is summarized as including a step for using a circuit for measuring (110; 810) a leakage current including a current measurement assembly (111; 811) and a second switch (112; 812) parallelly mounted, the second switch (112; 812) being suitable for receiving a first control signal (CTRL112; CTRL812) synchronized on a second control signal (CTRL101) of the first switch (101). In one embodiment, the current measurement assembly (111; 811) is suitable for measuring a current flowing through the first switch (101) as it is conductive.

In one embodiment, the second switch (112; 812) is suitable for receiving a minimum intensity current equal to the intensity of a current flowing through the first switch (101) as it is conductive.

In one embodiment, an electronic device includes a circuit, and the first switch (101).

In one embodiment, the circuit is coupled between a first conduction terminal of the first switch (101) and a load (Load100).

In one embodiment, the circuit is coupled between a second conduction, different from the first conduction terminal, of the first switch (101) and a terminal suitable for receiving a reference potential.

In one embodiment, the first switch (101) is a power transistor.

In one embodiment, the first switch (101) is a high mobility electronic transistor (HEMT).

In one embodiment, the device further includes a control unit (113; 813) suitable for providing the first and second control signals (CTRL101, CTRL112; CTRL812).

In one embodiment, the control unit (113; 300; 813) includes: at least one logic circuit (301); a first driver circuit (306) of the first switch (101); and a second driver circuit (309) of the second switch (112; 812).

In one embodiment, the control unit (113; 300; 813) further includes: at least one RC filter (302, 304, 307); and at least one Schmitt trigger (303, 305, 308).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A circuit for measuring a leakage current of a first switch during a non-conductive state of the first switch, comprising:
a current measurement assembly; and
a second switch parallelly mounted, the second switch being suitable for receiving a first control signal synchronized on a second control signal of the first switch.

2. The circuit according to claim 1, wherein the current measurement assembly is suitable for measuring a current flowing through the first switch as it is conductive.

3. The circuit according to claim 1, wherein the second switch is suitable for receiving a minimum intensity current equal to the intensity of a current flowing through the first switch as it is conductive.

4. An electronic device, comprising:
a first switch;
a circuit coupled to the first switch and including:
a current measurement assembly; and
a second switch coupled in parallel with the current measurement assembly and configured to receive a first control signal synchronized on a second control signal of the first switch.

5. The electronic device of claim 4, wherein the circuit is configured to measure a leakage current of the first switch while the first switch is open.

6. The device according to claim 5, wherein the circuit is coupled between a first conduction terminal of the first switch and a load.

7. The device according to claim 5, wherein the circuit is coupled between a second conduction, different from the first conduction terminal, of the first switch and a terminal suitable for receiving a reference potential.

8. The device according to claim 5, wherein the first switch is a power transistor.

9. The device according to claim 5, wherein the first switch is a high mobility electronic transistor.

10. The device according to claim 5, further comprising a control unit suitable for providing the first and second control signals.

11. The device according to claim 10, wherein the control unit includes:
at least one logic circuit;
a first driver circuit of the first switch; and
a second driver circuit of the second switch.

12. The device according to claim 10, wherein the control unit further includes:
at least one RC filter; and
at least one Schmitt trigger.

13. A method, comprising:
providing a first control signal to a first switch;
providing, to a second switch of a circuit, a second control signal synchronized with the first control signal; and
measuring, with a current measurement assembly of the circuit connected in parallel with the second switch, a leakage current of the first switch while the first switch is in a non-conductive state.

14. The method of claim 13 further comprising measuring, with the current measurement assembly, a current flowing through the first switch as the first switch is in a conductive state.

15. The method of claim 13, further comprising receiving, with the second switch, a minimum intensity current equal to the intensity of a current flowing through the first switch as the first switch is in a conductive state.

16. The method of claim 13, wherein the circuit is coupled between a first conduction terminal of the first switch and a load.

17. The method of claim 13, wherein the circuit is coupled between a second conduction, different from the first conduction terminal, of the first switch and a terminal suitable for receiving a reference potential.

18. The method of claim 13, wherein the first switch is a power transistor.

19. The method of claim 13, wherein the first switch is a high mobility electronic transistor.

20. The method of claim 13, further comprising providing the first and second control signal to the first and second switches from a control unit. a control unit suitable for providing the first and second control signals.
